(19) United States
(12) Patent Application Publication
(10) Pub. No.: US 2021/0305422 A1
(43) Pub. Date: Sep. 30, 2021

(54) SILLICON CARBIDE POWER MOSFET WITH ENHANCED BODY DIODE

(71) Applicant: ZHEJIANG UNIVERSITY, Hangzhou (CN)

(72) Inventors: Kuang SHENG, Hangzhou (CN); Na REN, Hangzhou (CN); Qing GUO, Hangzhou (CN); Zhengyun ZHU, Hangzhou (CN)

(21) Appl. No.: 17/174,029

(22) Filed: Feb. 11, 2021

(30) Foreign Application Priority Data
Mar. 25, 2020 (CN) 202010217839.6

(51) Int. Cl. H01L 29/78; H01L 29/16; H01L 29/06; H01L 29/10; H01L 21/02; H01L 21/04; H01L 29/66

(52) U.S. Cl. CPC H01L 29/7806; H01L 29/1608; H01L 29/0696; H01L 29/66068; H01L 29/7813; H01L 21/02529; H01L 21/046; H01L 29/1095

(57) ABSTRACT

A silicon carbide power MOSFET with enhanced body diode applying a repetitive polygonal or circular layout design on a first surface, having: a substrate; an N-type SiC region with a first doping concentration formed on the substrate; a JFET region or a trench insulating gate region formed inside the N-type SiC region; a metal layer formed on the N-type SiC region; a P-type SiC region with a second doping concentration or a Schottky region, wherein the P-type SiC region is formed on one side of the JFET region or one side of the trench insulating gate region, the P-type SiC region and the metal layer are contacted directly forming an ohmic contact, the Schottky region and the metal layer are contacted directly forming a Schottky contact; and a conventional source region on another side of the JFET region.

### CROSS-REFERENCE TO RELATED APPLICATIONS

This application claims the benefit of CN application 202010217839.6, filed on Mar. 25, 2020, and incorporated herein by reference.

### TECHNICAL FIELD

The present invention generally relates to semiconductor devices, and more particularly but not exclusively relates to a silicon carbide (SiC) power MOSFET (Metal-Oxide-Semiconductor Field Effect Transistor) with enhanced body diode.

### BACKGROUND

Conventional silicon-based semiconductor power devices have gradually reached their material limit. Meanwhile, the third-generation semiconductor power devices (represented by SiC-based ones), featuring high working frequency, high working voltage, high working temperature and good radiation resistance, have revealed feasibility for higher power density and higher system efficiency.

As a representative SiC power device, SiC MOSFET features low switching loss, high working frequency, good drivability and suitability for paralleled use. Nowadays, SiC MOSFET has been gradually popularized and used in electric vehicles, charging piles, new energy power generation, industrial control, flexible DC power transmission and other applications. FIG. 1 schematically shows a cross-sectional view of a conventional power MOSFET cell 000, comprising a drain electrode 1, a source electrode 11, a first insulating gate region 13, a substrate 2, a first N-type SiC region 3, a first source region 12 and a JFET region 7. The first N-type SiC region 3 is grown on the substrate 2 with a first N-type doping, comprising a first surface 14. The substrate 2 comprises a second surface 15. The JFET region 7 is adjacent to the first N-type SiC region 3. The first source region 12 is formed on the first N-type region 3 and on both sides of the JFET region 7, wherein the first source region comprises a second N-type region 5, a second P-type region 4 and a third P-type region 6. The second N-type region 5 has a second N-type doping. The second P-type region 4 has a second P-type doping. The third P-type region 6 has a third P-type doping. The first insulating gate region 13 is formed over JFET region 7 and the first source region 12, comprising a gate oxide layer 8, a gate electrode layer 9 and a passivation layer 10. The source electrode 11 comprises a first metal layer which extends on the first surface 14, contacts directly with the first source region 12 and forms an ohmic contact 001. The drain electrode 1 comprises a second metal layer which extends on the second surface 15, contacts directly with the substrate 2 and forms an ohmic contact 002.

Compared with traditional silicon IGBT modules, SiC MOSFET possesses lower conducting loss and higher switching frequency to improve system efficiency. Furthermore, the intrinsic body diode in SiC MOSFET substitutes for the paralleled freewheeling diode, which reduces circuit design complexity and system costs. However, in the development of power electronic system, apart from higher working efficiency and higher power density, higher system robustness and reliability is also another important indicator. When short-circuit failure takes place in power electronic system and protective circuit fails to function, a large surge current will flow through the body diode of SiC MOSFET and brings transient heat accumulation. When the SiC MOSFET's junction temperature exceeds the safe operating range, the SiC MOSFET is under the risk of breakdown. When SiC MOSFET fails from surge current stress, its gate and source terminal is short-circuited. As a result, the switching capability of SiC MOSFET is lost. As the operation failure of SiC MOSFET is detrimental to the power electronic system, the surge reliability of SiC MOSFET should be improved.

### SUMMARY

It is an object of the present invention to provide a SiC power MOSFET with enhanced body diode and associated manufacturing method.

An embodiment of the present invention is directed to a SiC power MOSFET with enhanced body diode, comprising at least one enhanced body diode cell applying a polygonal or circular layout design, wherein the enhanced body diode cell comprises: a substrate; a SiC region of a first doping type formed on the substrate; a first JFET region or a trench insulating gate region formed inside the SiC region of the first doping type; a metal layer formed on the SiC region of the first doping type; a SiC region of a second type doping or a Schottky region, wherein the SiC region of the second doping type is formed on a first side of the first JFET region or one side of the trench insulating gate region, the SiC region of the second doping type and the metal layer are contacted directly forming an ohmic contact, the Schottky region is formed on the first side of the first JFET region or one side of the trench insulating gate region, the Schottky region and the metal layer are contacted directly forming a Schottky contact; and a first conventional source region on a second side of the first JFET region, wherein the first side of the first JFET region is opposite to the second side of the first JFET region.

An embodiment of the present invention are directed to a SiC power MOSFET with enhanced body diode, comprising a plurality of enhanced body diode cells applying a polygonal or circular layout design, wherein each of the plurality of enhanced body diode cell comprises: a substrate; a SiC region of a first doping type formed on the substrate; a JFET region or a trench insulating gate region formed inside the SiC region of the first doping type; a metal layer formed on the SiC region of the first doping type; a SiC region of a second doping type or a Schottky region formed on a first side of the JFET region or one side of the trench insulating gate region, wherein the SiC region of the second doping type and the metal layer are contacted directly forming an ohmic contact, the Schottky region is formed on the first side of the first JFET region or one side of the trench insulating gate region, the Schottky region and the metal layer are contacted directly forming a Schottky contact; and a conventional source region formed on a second side of the JFET region, wherein the conventional source region comprises a body region of the second doping type and a source region of the first doping type, and the conventional source region and the metal layer are contacted directly forming an ohmic contact, wherein the conventional source regions of two adjacent enhanced body diode cells are contacted, or the SiC regions of the second doping type of the two adjacent enhanced body diode cells are contacted, or the Schottky regions of the two adjacent enhanced body diode cells are contacted.

Another embodiment of the present invention are directed to a method for manufacturing the enhanced body diode SiC power MOSFET with enhanced body diode, comprising: epitaxially growing a first SiC region of a first doping type on the substrate; forming a first SiC region of a second doping type via implantation on the first SiC region of the first doping type; forming a first source region via multi-step implantation, wherein the first source region comprises a second SiC region of the first doping type, a second SiC region of the second doping type and a third SiC region of the second doping type; simultaneously forming a JFET region between the first source region and the first SiC region of the second doping type; forming a gate insulating gate region over the first SiC region of the first doping type; depositing a first metal layer over the first SiC region of the first doping type and the insulating gate region; and depositing a second metal layer beneath the substrate.

The present invention can significantly increase an area of body diode, leading to a larger current capacity and a higher surge capability without degrading a current capacity of MOSFET. The present invention avoids sacrificing a performance of MOSFET while raising the current capacity and surge capability of body diode, thus achieving an improvement and balance between device performance and reliability. The present invention is feasible in laboratories and industrial manufacture, promising a good application prospect.

### BRIEF DESCRIPTION OF THE DRAWINGS

The present invention can be further understood with reference to the following detailed description and the appended drawings, wherein like elements are provided with like reference numerals. The drawings are only for illustration purpose. They may only show part of the devices and are not necessarily drawn to scale.

FIG. 1 schematically shows a cross-sectional view of a conventional power MOSFET cell 000.

FIG. 2a schematically shows a cross-sectional view of an enhanced body diode power MOSFET cell 100 with an embodiment of the present invention.

FIG. 2b schematically shows a top view of a SiC power MOSFET 100a with an embodiment of the present invention, wherein the SiC power MOSFET 100a comprises a plurality of enhanced body diode power MOSFET cells 100 shown in FIG. 2a. The enhanced body diode power MOSFET cells 100 apply a hexagonal design and are arranged periodically in a plurality of directions in SiC power MOSFET 100a.

FIG. 3a schematically shows a cross-sectional view of an enhanced body diode power MOSFET cell 200 with an embodiment of the present invention.

FIG. 3b schematically shows a top view of a SiC power MOSFET 200a with an embodiment of the present invention, wherein the SiC power MOSFET 200a comprises a plurality of enhanced body diode power MOSFET cells 200 shown in FIG. 3a. The enhanced body diode power MOSFET cells 100 apply a hexagonal design and are arranged periodically in a plurality of directions in SiC power MOSFET 200a.

FIG. 4a schematically shows a top view of a SiC power MOSFET 300 with an embodiment of the present invention, wherein the SiC power MOSFET 300 comprises a plurality of enhanced body diode power MOSFET cells 100 shown in FIG. 2a and a plurality of conventional power MOSFET cells 000 shown in FIG. 1. The enhanced body diode power MOSFET cells 100 apply a hexagonal design and are arranged periodically in a plurality of directions in SiC power MOSFET 300.

FIG. 4b schematically shows a top view of a SiC power MOSFET 300a with an embodiment of the present invention, wherein comprising at least one enhanced body diode power MOSFET cell 100 shown in FIG. 2a.

FIG. 5 schematically shows a top view of a SiC power MOSFET 400 with an embodiment of the present invention, wherein the SiC power MOSFET 400 comprises a plurality of enhanced body diode power MOSFET cells 100 shown in FIG. 2a. The enhanced body diode power MOSFET cells 100 apply a quadrilateral design and are arranged periodically in a plurality of directions in SiC power MOSFET 400.

FIG. 6 schematically shows a top view of a SiC power MOSFET 500 with an embodiment of the present invention, wherein the SiC power MOSFET 500 comprises a plurality of enhanced body diode power MOSFET cells 100 shown in FIG. 2a. The enhanced body diode power MOSFET cells 100 apply a circular design and are arranged periodically in a plurality of directions in SiC power MOSFET 500.

FIG. 7 schematically shows a top view of a SiC power MOSFET 800 with an embodiment of the present invention, wherein the SiC power MOSFET 800 comprises a plurality of enhanced body diode power MOSFET cells 100 shown in FIG. 2a. The enhanced body diode power MOSFET cells 100 apply quadrilateral or octagonal designs and are arranged periodically in a plurality of directions in SiC power MOSFET 800 in the same design or in different designs.

FIG. 8a schematically shows a cross-sectional view of an enhanced body diode power MOSFET cell 700 with an embodiment of the present invention.

FIG. 8b schematically shows a top view of a SiC power MOSFET 700a with an embodiment of the present invention, wherein the SiC power MOSFET 700a comprises a plurality of enhanced body diode power MOSFET cells 700 shown in FIG. 8a. The enhanced body diode power MOSFET cells 700 apply a hexagonal design and are arranged periodically in a plurality of directions in SiC power MOSFET 700a.

FIG. 9 schematically shows a cross-sectional view of an enhanced body diode power MOSFET cell 800 with an embodiment of the present invention.

FIG. 10 schematically shows a cross-sectional view of a method for manufacturing the enhanced body diode SiC power MOSFET 900 with an embodiment of the present invention.

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well-known methods, procedures, components, and circuits have not been described in detail so as not to unnecessarily obscure aspects of the present invention.

The terms “left,” right,” “in,” “out,” “front,” “back,” “up,” “down, “top,” “atop”, “bottom,” “over,” “under,” “beneath,” “above,” “below” and the like in the description and the claims, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein.

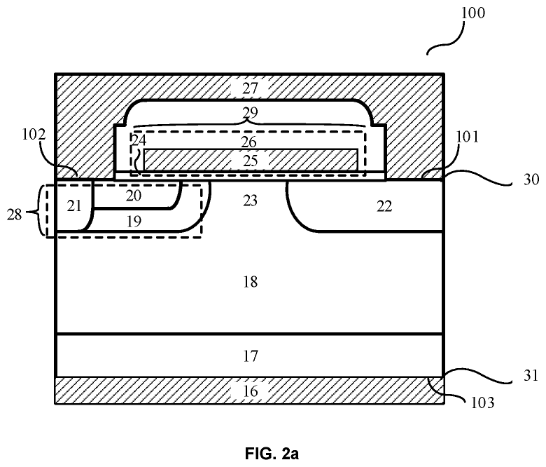

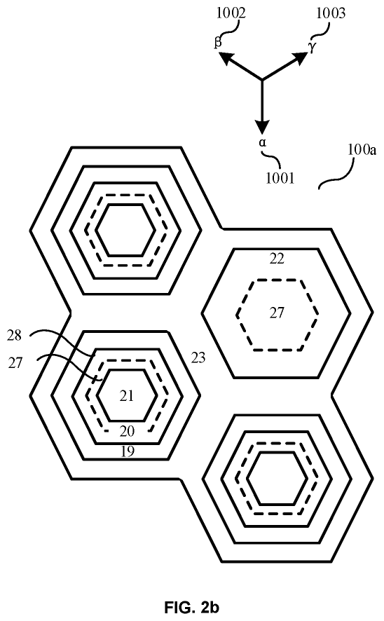

FIG. 2a schematically shows a cross-sectional view of an enhanced body diode power MOSFET cell 100 with an embodiment of the present invention. The enhanced body diode power MOSFET cell 100 comprises a drain electrode 16, a source electrode 27, a first insulating gate region 29, a substrate 17, a first N-type SiC region 18, a first P-type SiC region 22, a first source region 28 and a JFET region 23. The first N-type SiC region 18 is grown on the substrate 17 with a first N-type doping concentration, comprising a first surface 30. The substrate 17 comprises a second surface 31. The JFET region 23 is adjacent to the first N-type SiC region 18. The first P-type region 22 is formed on the first N-type region 18 and on the one side of JFET region 23, with a first P-type doping concentration. The first source region 28 is formed on the first N-type region 18 and on the other side of JFET region 23, wherein the first source region 28 comprises a second N-type region 20, a second P-type region 19 and a third P-type region 21. The second N-type region 20 has a second N-type doping concentration. The second P-type region 19 has a second P-type doping concentration. The third P-type region 21 has a third P-type doping concentration. In one embodiment of the present invention, the first P-type doping concentration and the second N-type doping concentration are both heavy doping concentration (e.g., over 1×10¹⁹ cm⁻³). And the third P-type doping concentration may be the same with the first P-type doping concentration, or slightly higher or lower than the first P-type doping concentration. The second P-type doping concentration should be lower than the first P-type doping concentration and the third P-type doping concentration. The first insulating gate region 29 is formed over JFET region 23, the first P-type SiC region 22 and the first source region 28, wherein the first insulating gate region 29 comprises a gate oxide layer 24, a gate electrode layer 25 and a passivation layer 26. The source electrode 27 comprises a first metal layer which extends on the first surface 30, contacts directly with both the first p-type SiC region 22 and the first source region 28 and forms an ohmic contact 101 and an ohmic contact 102. The drain electrode 16 comprises a second metal layer which extends on the second surface 31, contacts directly with the substrate 17 and forms an ohmic contact 103.

The substrate 17 may be 4H—SiC or 6H—SiC.

The JFET region 23 and the first N-type SiC region 18 may belong to an identical N-type epitaxial layer, or different N-type epitaxial layers. The JFET region 23 may be formed via implantation into the first N-type SiC region 18.

The gate electrode layer 25 may be N-type or P-type doped polysilicon, or metal like nickel, tungsten, or compound like titanium nitride.

The source electrode 27 and the drain electrode 16 may be metal like copper, aluminum, nickel and titanium.

In one embodiment of the present invention, when the gate electrode layer 25 is applied with negative voltage and the source electrode 27 is conducting large current or flooded with surge current, the first P-type SiC region 22 and the first N-type SiC region 27 build up an p-i-n body diode. Thanks to the large area of the first P-type SiC region 22, the device resistance is significantly reduced and the device's current capacity and surge capability is improved.

FIG. 2b schematically shows a top view of an enhanced body diode power MOSFET 100a with an embodiment of the present invention, wherein the enhanced body diode power MOSFET 100a comprises a plurality of enhanced body diode power MOSFET cells 100. In one embodiment of the present invention, the first P-type SiC region 22 and the first source region 28 both apply hexagonal design and are arranged periodically on the first direction α1001, the second direction 81002 and the third direction γ1003. Compared with traditional stripe design, the hexagonal design improves the integration level of the device, leading to a higher current capacity and a higher surge capability under a same active region area. The JFET region 23 is between the first source region 28 and the first P-type SiC region 22. The first source region 28 comprises a second N-type region 20, a second P-type region 19 and a third P-type region 21, wherein the second N-type region 20, the second P-type region 19 and the third P-type region 21 all apply hexagonal design. The first P-type SiC region 22 also applies hexagonal design. In one embodiment of the present invention, a ratio of the number of the first source region 28 to that of the first P-type SiC region 22 can be 2:1.

Arrangements of the first source region 28 and the first P-type SiC region 22 is based on the practical demand, while the arrangements can obey following rules: The number of the first P-type region 22 on both sides of the JFET region 23 is not larger than one, in order not to narrow current paths in the first N-type SiC region 18 when the device conducts current; The first P-type SiC region 22 is uniformly arranged on the first surface 30 to avoid local overheat when the device conducts current.

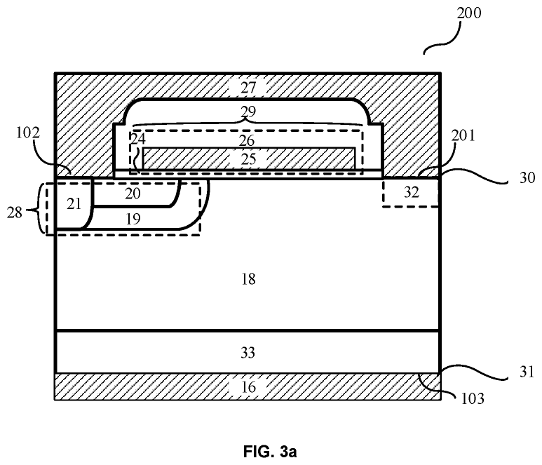

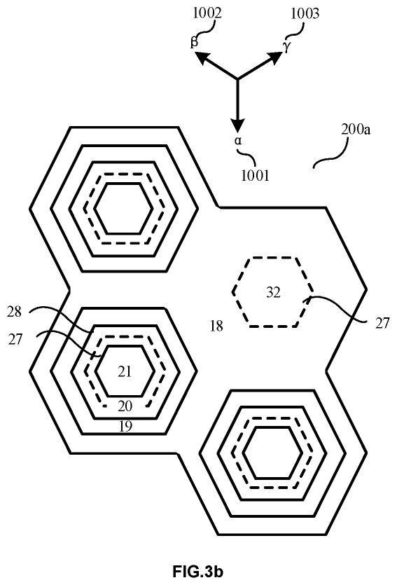

FIG. 3a schematically shows a cross-sectional view of an enhanced body diode power MOSFET cell 200 with an embodiment of the present invention, wherein the enhanced body diode power MOSFET cell 200 comprises a drain electrode 16, a source electrode 27, a first insulating gate region 29, a substrate 17, a first N-type SiC region 18, a first source region 28 and a Schottky region 32. The first N-type SiC region 18 is grown on the substrate 17 with a first N-type doping concentration, comprising a first surface 30. The substrate 17 comprises a second surface 31. The Schottky region 32 is adjacent to the first N-type region 18, with a third N-type doping concentration. The third N type doping concentration may be the same with the first N-type doping concentration, or larger than the first N-type doping concentration. The first source region 28 is formed on the first N-type region 18, comprising a second N-type region 20, a second P-type region 19 and a third P-type region 21. The second N-type region 20 has a second N-type doping concentration. The second P-type region 19 has a second P-type doping concentration. The third P-type region 21 has a third P-type doping concentration. In one embodiment of the present invention, the first P-type doping concentration and the second N-type doping concentration are both heavy doping concentration. And the third P-type doping concentration may be the same with the first P-type doping concentration, or slightly higher or lower than the first P-type doping concentration. The second P-type doping concentration should be lower than the first P-type doping concentration and the third P-type doping concentration. The first insulating gate region 29 is formed over the first N-type SiC region 18 and the first source region 28, wherein the first insulating gate region 29 comprises a gate oxide layer 24, a gate electrode layer 25 and a passivation layer 26. The source electrode 27 comprises a first metal layer which extends on the first surface 30, contacts directly with Schottky region 32 and forms an Schottky contact 201, and simultaneously contacts directly with the first source region 28 and forms an ohmic contact 102. The drain electrode 16 comprises a second metal layer which extends on the second surface 31, contacts directly with the substrate 17 and forms an ohmic contact 103.

FIG. 3b schematically shows a top view of an enhanced body diode power MOSFET 200a with an embodiment of the present invention, wherein the enhanced body diode power MOSFET 200a comprises a plurality of enhanced body diode power MOSFET cells 200. In one embodiment of the present invention, the Schottky region 32 and the first source region 28 both apply hexagonal design and are arranged periodically in the first direction α 1001, the second direction β 1002 and the third direction γ 1003. Compared with traditional stripe design, the hexagonal design improves an integration level of the device, leading to a higher current capacity and a higher surge capability under the active region area. The first source region 28 comprises a second N-type region 20, a second P-type region 19 and a third P-type region 21, wherein the second N-type region 20, the second P-type region 19 and the third P-type region 21 all apply hexagonal design. The Schottky region 32 also applies hexagonal design. In one embodiment of the present invention, the ratio of the number of the first source region 28 to that of the first P-type SiC region 32 can be 2:1.

A difference between the enhanced body diode power MOSFET cell 200 in FIG. 3a and the enhanced body diode power MOSFET cell 100 in FIG. 2a and a difference between the SiC power MOSFET 200a in FIG. 3b and the SiC power MOSFET 100a in FIG. 2b appear in a substitution of the Schottky region 32 to the first P-type SiC region 22, leading to a Schottky contact 201 between the Schottky region 32 and the source electrode 27 on the first surface 30. In enhanced body diode power MOSFET cell 200, the Schottky diode switches on prior to the body diode when the device switches off, which significantly improves a switch speed of the device.

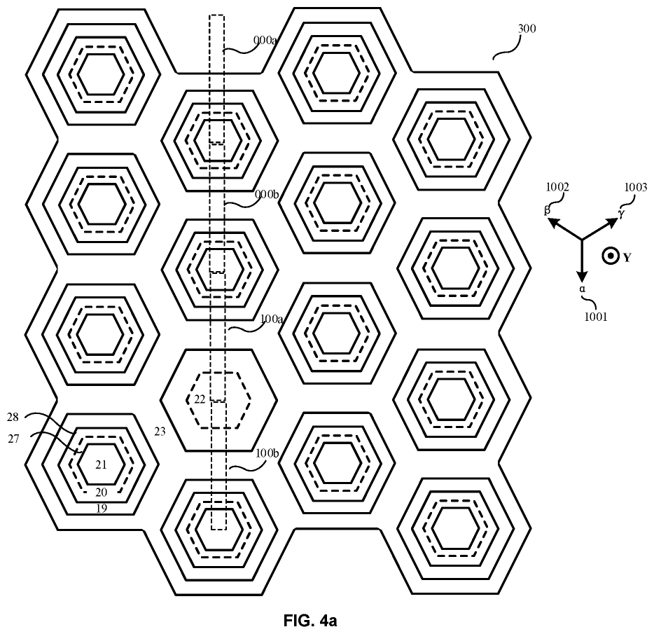

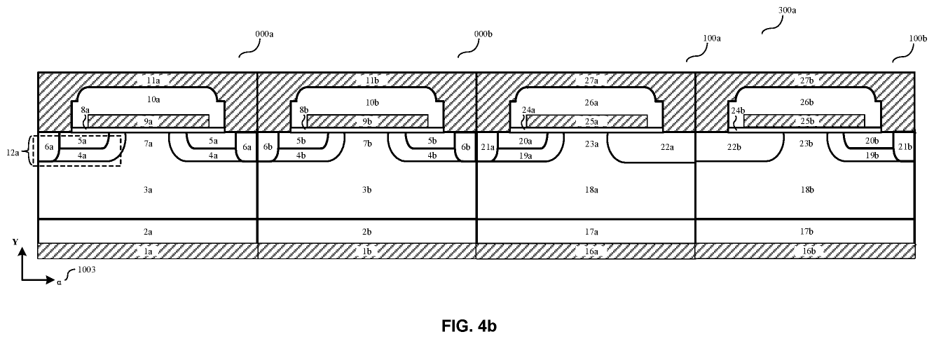

FIG. 4a schematically shows a top view of an enhanced body diode power MOSFET 300 with an embodiment of the present invention, wherein the enhanced body diode power MOSFET 300 comprises a plurality of enhanced body diode power MOSFET cells 100 and a plurality of conventional power MOSFET cells (e.g. the conventional power MOSFET cell 000a and the conventional power MOSFET cell 000b). A difference between the SiC power MOSFET 300 in FIG. 4a and the SiC power MOSFET 100a in FIG. 2b appears in an insertion of conventional power MOSFET cells among periodically arranged enhanced body diode power MOSFET cells 100 in the first direction α 1001, the second direction β 1002 and the third direction γ 1003. In one embodiment of the present invention, the ratio of the number of the two cells can be 1:1 in any of the first direction α 1001, the second direction β 1002 and the third direction γ 1003. In FIG. 4a, a minimum period of cell number in the first direction a 1001 is four, wherein the four cells are 000a, 000b, 100a and 100b. In one embodiment, the ratio of the number of the first source region 28 to that of the first P-type SiC region 22 can be 8:1. It is worthy noticing that the ratio of the number of the first source region 28 to that of the first P-type SiC region 22 may be any other value, by altering the ratio of the enhanced body diode power MOSFET cell 100 to that of the conventional power MOSFET cell 000. By altering the ratio of the first P-type SiC region 22 in the active area of the device, a new variable is introduced for cell design, thus it efficiently avoids sacrificing the performance of MOSFET while significantly raising the current capacity and surge capability of body diode. This method works in all designs with a polygonal first P-type SiC region 22.

FIG. 4b schematically shows a cross-sectional view of an enhanced body diode power MOSFET 300a with an embodiment of the present invention, wherein the enhanced body diode power MOSFET 300a comprises a plurality of enhanced body diode power MOSFET cells 100 and a plurality of conventional power MOSFET cells (e.g. the conventional power MOSFET cell 000a and the conventional power MOSFET cell 000b). In the minimum period, four adjacent cells 000a, 000b, 100a and 100b are arranged in the first direction α 1001. Cells 000a and 000b are conventional power MOSFET cells. The cell 000a comprises a drain electrode 1a, a source electrode 11a, a substrate 2a, a first N-type SiC region 3a, a JFET region 7a, a second N-type SiC region 5a, a second P-type SiC region 4a, a third P-type SiC region 6a, a gate oxide layer 8a, a gate electrode layer 9a and a passivation layer 10a. A structure of the cell 000b is the same as that of the cell 000a. The cells 100a and 100b are enhanced body diode power MOSFET cells. The cell 100a comprises a drain electrode 16a, a source electrode 27a, a substrate 17a, a first N-type SiC region 18a, a JFET region 23a, a first P-type SiC region 22a, a second N-type SiC region 20a, a second P-type SiC region 19a, a third P-type SiC region 21a, a gate oxide layer 24a, a gate electrode layer 25a and a passivation layer 26a.

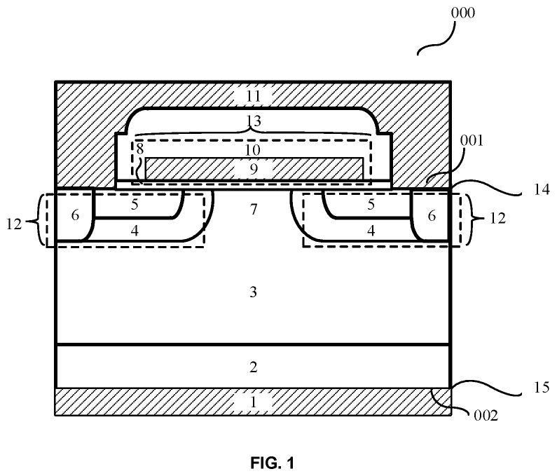

In an embodiment of the present invention, the said conventional power MOSFET cells can be the same with the conventional power MOSFET cell 000 as shown in FIG. 1, i.e. the conventional power MOSFET cell 000a or the conventional power MOSFET cell 000b can be the same with the conventional power MOSFET cell 000 as shown in FIG. 1. In an embodiment shown in FIG. 4a, the enhanced body diode power MOSFET 300 comprises at least one conventional power MOSFET cell 000a applying a polygonal or circular layout design, wherein the at least one conventional power MOSFET 000a comprises two conventional source regions 12a formed on both sides of the JFET region 7a as shown in FIG. 4b.

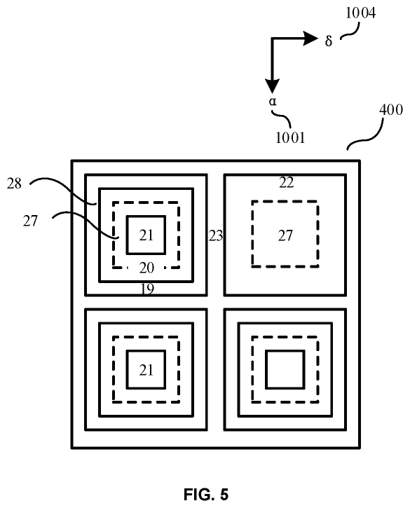

FIG. 5 schematically shows a top view of an enhanced body diode power MOSFET 400 with an embodiment of the present invention, wherein the enhanced body diode power MOSFET 400 comprises a plurality of enhanced body diode power MOSFET cells 100. A difference between the SiC power MOSFET 400 in FIG. 5 and the SiC power MOSFET 100a in FIG. 2b appears in the quadrilateral design of the first source region 28 and the first P-type SiC region 22 which are periodically arranged in the first direction a 1001 and the fourth direction δ 1004. Compared with traditional stripe design, the quadrilateral design improves the integration level of the device, leading to a higher current capacity and a higher surge capability under the same active region area. It is worthy noticing that the ratio of the number of the first source region 28 to that of the first P-type SiC region 22 may be any other value besides that in FIG. 5.

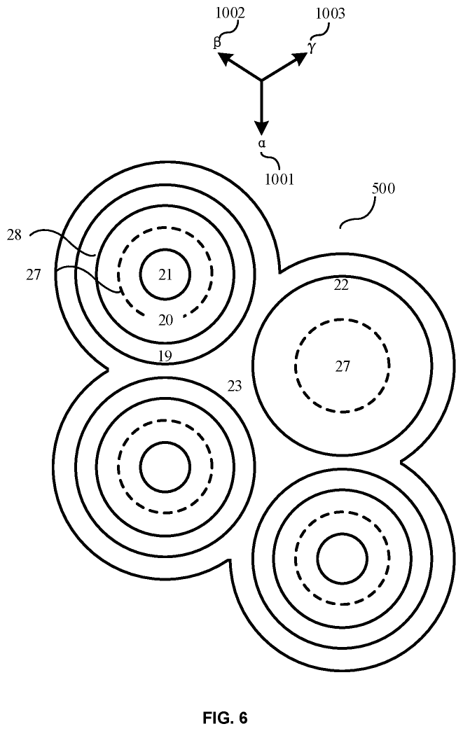

FIG. 6 schematically shows a top view of an enhanced body diode power MOSFET 500 with an embodiment of the present invention, wherein the enhanced body diode power MOSFET 500 comprises a plurality of enhanced body diode power MOSFET cells 100. A difference between the SiC power MOSFET 500 in FIG. 6 and the SiC power MOSFET 100a in FIG. 2b appears in the circular design of the first source region 28 and the first P-type SiC region 22 which are periodically arranged in the first direction α 1001, the second direction β 1002 and the third direction γ 1003. Compared with traditional stripe design, the circular design improves the integration level of the device, leading to a higher current capacity and a higher surge capability under the same active region area. In addition, the circular design simultaneously alleviates the electric field crowding phenomenon while the device is blocking a high voltage. It is worthy noticing that the ratio of the number of the first source region 28 to that of the first P-type SiC region 22 may be any other value besides that in FIG. 6.

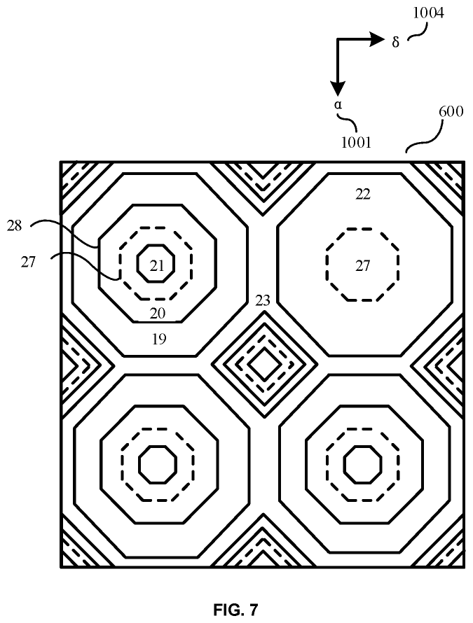

FIG. 7 schematically shows a top view of an enhanced body diode power MOSFET 600 with an embodiment of the present invention, wherein the enhanced body diode power MOSFET 600 comprises a plurality of enhanced body diode power MOSFET cells 100. The enhanced body diode power MOSFET cells 100 apply an octagonal or quadrilateral design arranged periodically in a plurality of directions in power MOSFET 600. A difference between the SiC power MOSFET 600 in FIG. 7 and the SiC power MOSFET 100a in FIG. 2b appears in the octagonal design of the first source region 28 and the first P-type SiC region 22 which are periodically arranged in the first direction a 1001 and the fourth direction δ 1004. Gaps among octagons are filled with the first source region 28 in quadrilateral design. It is worthy noticing that the ratio of the number of the first source region 28 to that of the first P-type SiC region 22 may be any other value besides that in FIG. 7. In one embodiment of the present invention, the gaps among the octagons are filled with quadrilateral JFET region instead of the first source region 28. In one embodiment of the present invention, the gaps among the octagons are filled with not only the first source region 28, but also the first P-type SiC region 22. It is worthy noticing that the ratio of the number of the filling quadrilateral first source region 28 to that of the filling quadrilateral first P-type SiC region 22 may be any other value besides that in FIG. 7. Compared with traditional stripe design, the octagonal design improves the integration level of the device, leading to a higher current capacity and a higher surge capability under the same active region area. In addition, the octagonal design achieves a less crowding electric field than hexagonal or quadrilateral counterparts while the device is blocking a high voltage.

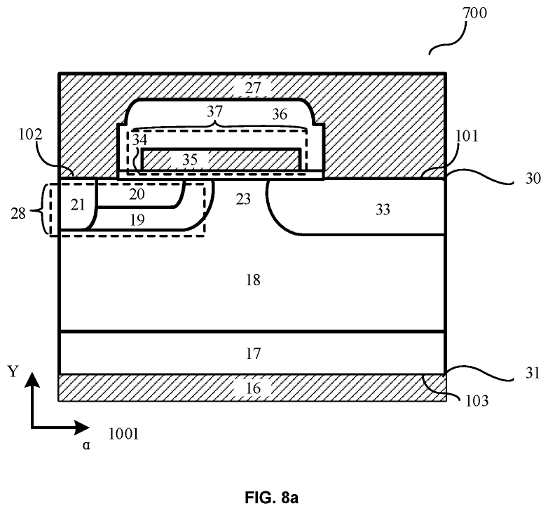

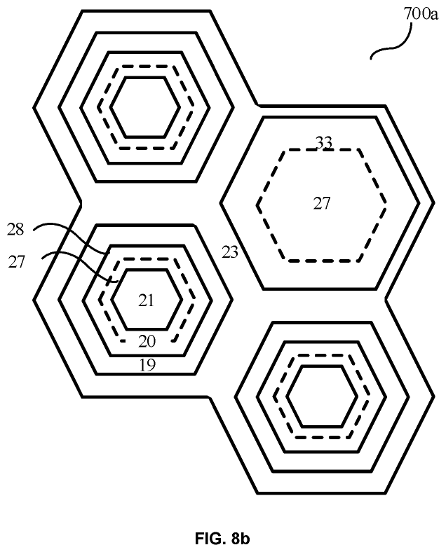

FIG. 8a schematically shows a cross-sectional view of an enhanced body diode power MOSFET cell 700 with an embodiment of the present invention, wherein the enhanced body diode power MOSFET cell 700 comprises a drain electrode 16, a source electrode 27, a second insulating gate region 37, a substrate 17, a first N-type SiC region 18, a fourth P-type SiC region 33, a first source region 28 and a JFET region 23. The first N-type SiC region 18 is grown on the substrate 17 with a first N-type doping concentration, comprising a first surface 30. The substrate 17 comprises a second surface 31. The JFET region 23 is adjacent to the first N-type SiC region 18. The fourth P-type region 33 with a first P-type doping concentration is formed on the first N-type region 18 and on one side of JFET region 23. The first source region 28 is formed on the first N-type region 18 and on the other side of JFET region 23, wherein the first source region 28 comprises a second N-type region 20, a second P-type region 19 and a third P-type region 21. The second N-type region 20 has a second N-type doping concentration. The second P-type region 19 has a second P-type doping concentration. The third P-type region 21 has a third P-type doping concentration. In one embodiment of the present invention, the first P-type doping concentration and the second N-type doping concentration can be heavy doping. And the third P-type doping concentration may be the same with the first P-type doping concentration, or slightly higher or lower than the first P-type doping concentration. In one embodiment of the present invention, the second P-type doping concentration should be lower than the first P-type doping concentration and the third P-type doping concentration. The second insulating gate region 37 is formed over the JFET region 23, the fourth P-type SiC region 33 and the first source region 28, wherein the second insulating gate region 37 comprises a gate oxide layer 34, a gate electrode layer 35 and a passivation layer 36. The source electrode 27 comprises a first metal layer which extends on the first surface 30, contacts directly with both the fourth p-type SiC region 33 and the first source region 28 and forms the ohmic contact 101 and the ohmic contact 102. The drain electrode 16 comprises a second metal layer which extends on the second surface 31, contacts directly with the substrate 17 and forms an ohmic contact 103.

FIG. 8b schematically shows a top view of an enhanced body diode power MOSFET 700a with an embodiment of the present invention, wherein the enhanced body diode power MOSFET 700a comprises a plurality of enhanced body diode power MOSFET cells 200. In one embodiment of the present invention, the fourth P-type SiC region 33 and the first source region 28 both apply hexagonal design and are arranged periodically in the first direction α 1001, the second direction β 1002 and the third direction γ 1003. The JFET region 23 is between the first source region 28 and the fourth P-type SiC region 33. The first source region 28 comprises the second N-type region 20, the second P-type region 19 and the third P-type region 21, wherein the second N-type region 20, the second P-type region 19 and the third P-type region 21 all apply hexagonal design. The fourth P-type SiC region 33 also applies hexagonal design. In one embodiment of the present invention, the ratio of the number of the first source region 28 to that of the first P-type SiC region 33 is 2:1.

A difference between the enhanced body diode power MOSFET cell 700 in FIG. 8a and the enhanced body diode power MOSFET cell 100 in FIG. 2a and a difference between the SiC power MOSFET 700a in FIG. 8b and the SiC power MOSFET 100a in FIG. 2b appear in the substitution of the fourth P-type SiC region 33 to the first P-type SiC region 22 and the substitution of the second insulating gate region 37 to the first insulating gate region 29. In enhanced body diode power MOSFET cell 700, a length of the fourth P-type SiC region 33 is longer than that of the first P-type SiC region 22 in the first direction a 1001, and a length of the second insulating gate region 37 is shorter than that of the first insulating gate region 29. This leads to a larger ohmic contact area 101 and improves the device's current capacity and surge capability.

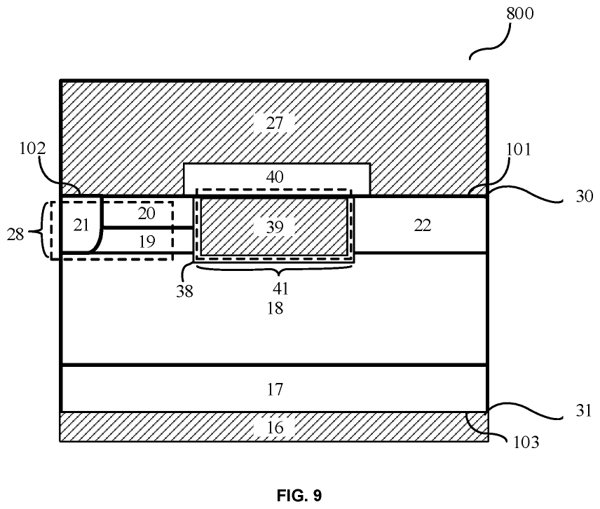

FIG. 9 schematically shows a cross-sectional view of an enhanced body diode power MOSFET cell 800 with an embodiment of the present invention, wherein the enhanced body diode power MOSFET cell 800 comprises a drain electrode 16, a source electrode 27, a third insulating gate region 41, a substrate 17, a first N-type SiC region 18, a first P-type SiC region 22 and a first source region 28. The first N-type SiC region 18 is grown on the substrate 17 with a first N-type doping concentration, comprising a first surface 30. The substrate 17 comprises a second surface 31. The third insulating gate region 41 is formed over the first N-type SiC region 18, wherein the third insulating gate region 41 comprises a gate oxide layer 38, a gate electrode layer 39 and a passivation layer 40. The first P-type region 22 is formed on the first N-type region 18 and on one side of the third insulating gate region 41, with a first P-type doping concentration. The first source region 28 is on the first N-type region 18 and on the other side of the third insulating gate region 23, comprising a second N-type region 20, a second P-type region 19 and a third P-type region 21. The second N-type region 20 has a second N-type doping concentration. The second P-type region 19 has a second P-type doping concentration. The third P-type region 21 has a third P-type doping concentration. In one embodiment of the present invention, the first P-type doping concentration and the second N-type doping concentration are both heavy doping concentration. And the third P-type doping concentration may be the same with the first P-type doping concentration, or slightly higher or lower than the first P-type doping concentration. In one embodiment of the present invention, the second P-type doping concentration should be lower than the first P-type doping concentration and the third P-type doping concentration. The source electrode 27 comprises a first metal layer which extends on the first surface 30, contacts directly with both the first p-type SiC region 22 and the first source region 28 and forms an ohmic contact 101 and an ohmic contact 102. The drain electrode 16 comprises a second metal layer which extends on the second surface 31, contacts directly with the substrate 17 and forms an ohmic contact 103. In another embodiment of the present invention, the enhanced body diode power MOSFET cell 800 can comprise a Schottky region 22 like the Schottky region 32 shown in FIG. 3a rather than the first P-type region 22. The Schottky region 22 contacts directly with the source electrode 27 and forms an Schottky contact 101.

A difference between the enhanced body diode power MOSFET cell 800 in FIG. 9 and the enhanced body diode power MOSFET cell 100 in FIG. 2a appears in a substitution of the third insulating gate region 41 to the first insulating region 29. In the enhanced body diode power MOSFET cell 800, a JFET resistance is eliminated, and thus a current capacity of the device is improved while maintaining the current capacity and surge capability of the body diode.

The embodiments in the FIG. 1 to FIG. 9 does not cover all the arrangement methods for enhanced body diode cells, including one polygonal design or a plurality of polygonal designs. The arrangement method and polygonal design may follow practical demand.

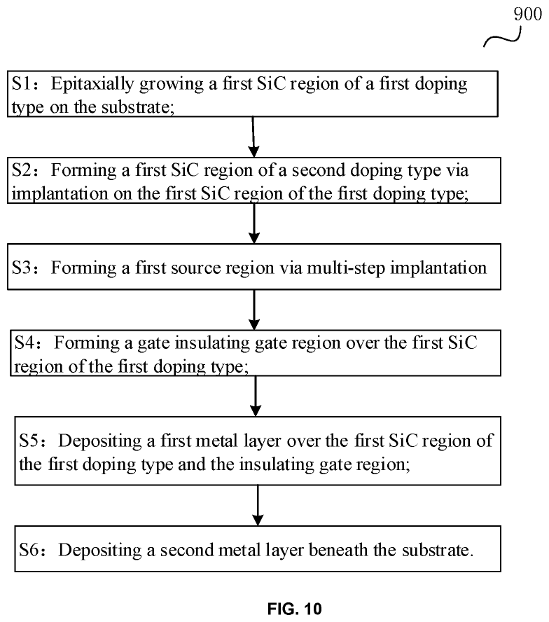

FIG. 10 schematically shows a method for manufacturing the SiC power MOSFET with enhanced body diode, comprising steps S1 to S6.

Step S1: epitaxially growing a first N-type SiC region with a first N-type doping concentration on the substrate.

Step S2: forming a first P-type SiC region via implantation with a first P-type doping concentration on the first N-type SiC region; In one embodiment of the present invention, a mask is needed for high temperature implantation to form the first P-type SiC region on the first N-type SiC region.

Step S3: forming a first source region via multi-step implantation, wherein the first source region comprises a second N-type SiC region with a second N-type doping concentration, the second P-type SiC region with a second P-type doping concentration, the third P-type SiC region with a third P-type doping concentration; Simultaneously forming a JFET region between the first source region and the first P-type SiC region; In one embodiment of the present invention, a mask is needed for high temperature implantation to form the JFET region on the first N-type SiC region with a fourth N-type doping concentration.

Step S4: forming a gate insulating gate region over the first N-type SiC region; In one embodiment of the present invention, the oxide layer is formed via thermal oxidation; In another embodiment of the present invention, the oxide layer is formed via chemical vapor deposition (CVD).

Step S5: depositing a first metal layer over the first N-type SiC region and the insulating gate region; In one embodiment of the present invention, the first metal layer is deposited with copper instead of common-used aluminum to improve the melt point of the gate electrode and the source electrode, and thus the device's surge capability is improved.

Step S6: depositing a second metal layer beneath the substrate.

A person skilled in the art should know the above said N-type and P-type are not limited the only doping type, e.g. the present N-type can be P-type, and the present P-type can be N-type in other embodiments.

Obviously, many modifications and variations of the present invention are possible in light of the above teachings. It is therefore to be understood that within the scope of the appended claims the invention may be practiced otherwise than as specifically described. It should be understood, of course, the foregoing disclosure relates only to a preferred embodiment (or embodiments) of the invention and that numerous modifications may be made therein without departing from the spirit and the scope of the invention as set forth in the appended claims. Various modifications are contemplated and they obviously will be resorted to by those skilled in the art without departing from the spirit and the scope of the invention as hereinafter defined by the appended claims as only a preferred embodiment(s) thereof has been disclosed.

What is claimed is:

1. A SiC power MOSFET with enhanced body diode, comprising:
at least one enhanced body diode cell applying a polygonal or circular layout design, wherein the one enhanced body diode cell comprises:
a substrate;
a SiC region of a first doping type formed on the substrate;
a first JFET region or a trench insulating gate region formed inside the SiC region of the first doping type;
a metal layer formed on the SiC region of the first doping type;
a SiC region of a second doping type or a Schottky region, wherein the SiC region of the second doping type is formed on a first side of the first JFET region or one side of the trench insulating gate region, the SiC region of the second doping type and the metal layer are contacted directly forming an ohmic contact, the Schottky region is formed on the first side of the first JFET region or one side of the trench insulating gate region, the Schottky region and the metal layer are contacted directly forming a Schottky contact; and
a first conventional source region on a second side of the first JFET region, wherein the first side of the first JFET region is opposite to the second side of the first JFET region.

2. The SiC power MOSFET of claim 1, wherein the polygonal layout design is quadrilateral, hexagonal or octagonal.

3. The SiC power MOSFET of claim 1, wherein
the trench insulating gate region comprises a gate oxide layer, a gate electrode layer and a passivation layer;
the gate oxide layer is formed between the SiC region of the first doping type and the gate electrode layer; and
the passivation layer is formed over a top surface of the gate electrode layer.

4. The SiC power MOSFET of claim 1, wherein the first conventional source region comprises a body region of the second doping type and a source region of the first doping type, and the first conventional source region and the metal layer are contacted directly forming an ohmic contact.

5. The SiC power MOSFET of claim 1, further comprising: at least one conventional power MOSFET cell applying a polygonal or circular layout design, wherein the at least one conventional power MOSFET comprises two second conventional source regions formed on both sides of a second JFET region.

6. The SiC power MOSFET of claim 5, wherein in a certain direction among the at least one enhanced body diode cell, the at least one conventional power MOSFET cell is inserted.

7. The SiC power MOSFET of claim 1, wherein in a plurality of directions, the at least one enhanced body diode cell is arranged periodically.

8. The SiC power MOSFET of claim 7, wherein the SiC power MOSFET comprises four cells arranged in one of the plurality of directions, at least two of the four cells are enhanced body diode cells, and rest of the four cells are conventional power MOSFET cells.

9. The SiC power MOSFET of claim 7, wherein the SiC power MOSFET comprises two adjacent enhanced body diode cells, the conventional source regions of the two adjacent enhanced body diode cells are contacted, or the SiC regions of the second doping type of the two adjacent enhanced body diode cells are contacted, or the Schottky regions of the two adjacent enhanced body diode cells are contacted.

10. A SiC power MOSFET with enhanced body diode, comprising:
a plurality of enhanced body diode cells applying a polygonal or circular layout design, wherein each of the plurality of enhanced body diode cell comprises:
a substrate;
a SiC region of a first doping type formed on the substrate;
a JFET region or a trench insulating gate region formed inside the SiC region of the first doping type;
a metal layer formed on the SiC region of the first doping type;
a SiC region of a second doping type or a Schottky region formed on a first side of the JFET region or one side of the trench insulating gate region, wherein the SiC region of the second doping type and the metal layer are contacted directly forming an ohmic contact, the Schottky region is formed on the first side of the first JFET region or one side of the trench insulating gate region, the Schottky region and the metal layer are contacted directly forming a Schottky contact; and
a conventional source region formed on a second side of the JFET region, wherein the conventional source region comprises a body region of the second doping type and a source region of the first doping type, and the conventional source region and the metal layer are contacted directly forming an ohmic contact, wherein the conventional source regions of two adjacent enhanced body diode cells are contacted, or the SiC regions of the second doping type of the two adjacent enhanced body diode cells are contacted, or the Schottky regions of the two adjacent enhanced body diode cells are contacted.

11. The SiC power MOSFET of claim 10, wherein the plurality of enhanced body diode cells are arranged in the same layout design or different layout designs.

12. The SiC power MOSFET of claim 10, wherein the SiC power MOSFET comprises at least four cells in a certain direction, wherein
the four cells comprise a first conventional power MOSFET cell, a second conventional power MOSFET cell, a first enhanced body diode cell and a second enhanced body diode cell;
one conventional source region of the first conventional power MOSFET cell and one conventional source region of the second conventional power MOSFET cell are contacted directly;
another conventional source region of the second conventional power MOSFET cell and the conventional source region of the first enhanced body diode cell are contacted directly; and
the SiC region of the first doping type of the first enhanced body diode cell and the SiC region of the second doping type of the second enhanced body diode cell are contacted directly.

13. The SiC power MOSFET of claim 10, wherein in a certain direction among the plurality of enhanced body diode cells, conventional power MOSFET cells are inserted.

14. A method for manufacturing the SiC power MOSFET with enhanced body diode, comprising:
epitaxially growing a first SiC region of a first doping type on the substrate;
forming a first SiC region of a second doping type via implantation on the first SiC region of the first doping type;
forming a first source region via multi-step implantation, wherein the first source region comprises a second SiC region of the first doping type, a second SiC region of the second doping type and a third SiC region of the second doping type;
simultaneously forming a JFET region between the first source region and the first SiC region of the second doping type;
forming a gate insulating gate region over the first SiC region of the first doping type;
depositing a first metal layer over the first SiC region of the first doping type and the insulating gate region; and
depositing a second metal layer beneath the substrate.
